(19) United States
(12) Patent Application Publication
(10) Pub. No.: US 2004/0041638 A1
(43) Pub. Date: Mar. 4, 2004

(54) Digital modulation synthesizer

(76) Inventors: Guillaume Vilcocq, Courbevoie (FR); Corinne Brun, Jouy en Josas (FR)

Correspondence Address: Dan C Hu, Trop Pruner & Hu, 8554 Katy Freeway, Suite 100, Houston, TX, 77024, US

(21) Appl. No.: 10/296,862

(22) PCT Filed: May 23, 2001
(86) PCT No.: PCT/FR01/01606

(30) Foreign Application Priority Data
May 31, 2000 (FR) 00/07059

(51) Int. Cl. H03L 7/00

(52) U.S. Cl. 331/16

(57) ABSTRACT

The invention concerns a digital modulation synthesizer for generating an output frequency or phase modulated radiofrequency signal (S_{OUT}), comprising a pre-accentuation filter (18) receiving a frequency modulation digital signal (F_{mod}) in input to produce a pre-accentuated frequency modulation signal (F′_{mod}), a modulator Σ-Δ (15) having an input receiving the pre-accentuated frequency modulation signal (F′_{mod}), and an output delivering a pre-accentuated and scrambled frequency modulation signal (S_{c}), a phase locked loop (PLL) with variable radio frequency divider (14) in the feedback path, the filtering by the phase locked loop (PLL) enabling to filter the quantizing distortion introduced by the modulator Σ-Δ (15) and the pre-accentuation filter (18) applying a pre-accentuation to the frequency modulation signal (F_{mod}) enabling to compensate the effect of said filtering on the modulation inside a usful band, means for automatic calibration of the pre-accentuation filter (18) enabling further to adjust the pre-accentuation filter (18) function to that of the PLL.

The present invention relates to a digital modulation synthesizer, more commonly known as a DMS (standing for “Digitally Modulated Synthesizer”). Such a circuit can be used for generating a frequency-modulated or phase-modulated radiofrequency signal (in the UHF band lying between 400 and 600 MHz). It finds applications in transmitters of a radiocommunications system, in base stations and/or in mobile stations.

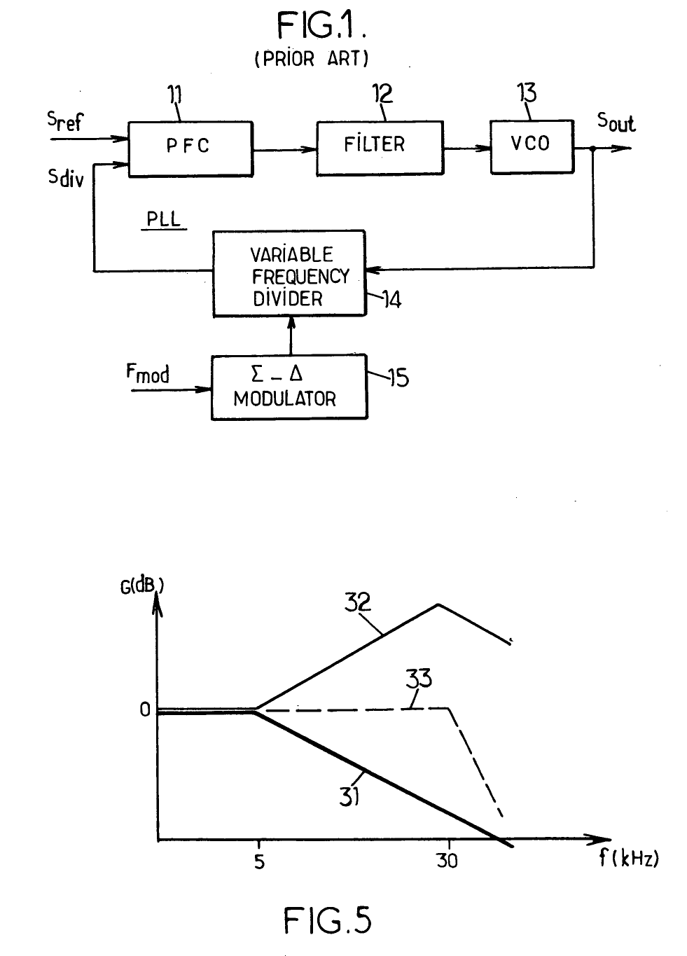

A DMS exhibits an architecture which is derived from the structure of a fractional frequency synthesizer, and makes it possible to generate a frequency-modulated or phase-modulated periodic signal. The functional diagram of a DMS known in the state of the art is represented in FIG. 1. The DMS comprises a phase locked loop 10 or PLL comprising in series a phase/frequency comparator 11 or PFC, a loop filter 12 such as an integrator, and a voltage-controlled oscillator 13 or VCO, as well as, in the return pathway, a frequency divider 14. The VCO outputs a signal Sₒᵤₜ which is the output signal from the DMS, whose instantaneous frequency is fₒᵤₜ. The PFC receives on a first input a reference signal S_{ref} having a reference frequency f_{ref} and, on a second input, a signal S_{div} obtained by the frequency divider 14 from the signal Sₒᵤₜ. For a conventional fractional synthesis, the frequency divider 14 is a variable-ratio divider making it possible to produce the signal S_{div} by dividing the frequency fₒᵤₜ of the signal Sₒᵤₜ by a division ratio which alternately equals an integer N for a fraction A of the time, and the integer N+1 for a fraction B of the time, so that the frequency fₒᵤₜ of the output signal Sₒᵤₜ is given as a function of the frequency f_{ref} of the reference signal S_{ref} by:

$${f}_{out} = ( N + \frac{B}{A + B} ) \times {f}_{ref} \qquad ( 1 )$$

The frequency divider 14 comprises a control input for the division ratio. This ratio is fixed by an accumulator in the manner described previously.

However, in order to avoid the appearance of spurious lines in the spectrum of the output signal Sₒᵤₜ due to the periodicity of the changes of the division ratio from N to N+1 and vice versa, the DMS known in the state of the art moreover comprises a modulator 15, of the type of a Σ-Δ modulator. The modulator 15 comprises an input which receives a frequency modulation digital signal F_{mod}, and an output which delivers a signal S_{c} corresponding to the scrambled signal F_{mod}. The output of the modulator 15 is linked to the control input of the divider 14 so as to deliver thereto the signal S_{c}. Thus connected, the modulator 15 makes it possible to provide for the signal S_{c} applied at each instant to the control input of the frequency divider 14 being a pseudo-random signal, thereby breaking the periodicity of the changes of the division ratio.

As is known, a Σ-Δ modulator performs oversampling and introduces quantization noise into the PLL. According to an intrinsic characteristic of this type of modulator, the quantization noise is shaped in such a way that its spectrum exhibits a slope which increases with frequency. Stated otherwise, the Σ-Δ modulator ensures a shaping of the quantization noise (or “noise shaping”) such that the quantization noise is essentially present in the high frequencies.

This quantization noise gives rise to phase noise in the output signal Sₒᵤₜ generated by the VCO. To eliminate the quantization noise introduced by the Σ-Δ modulator, it may prove to be necessary to adjust the cutoff frequency f_{c} of the PLL to a value which may be below the maximum frequency f_{mod} of the useful band of the frequency modulation signal F_{mod}. In order not to impair the modulation of the output signal Sₒᵤₜ, it is proposed that a pre-accentuation be applied to the modulation signal F_{mod}. This pre-accentuation is introduced by a digital filter, whose transfer function is matched to that of the PLL in a useful band. Moreover, in order to take account of the spread in the characteristics of the analog components making up the PLL (essentially of the components of the filter 12 and of the VCO), of their drift with temperature and/or of their aging, which cause the open-loop gain of the PLL and hence its cutoff frequency to vary, the invention proposes, for the pre-accentuation filter, a programmable digital filter associated with means of automatic calibration.

Specifically, the invention proposes a digital modulation synthesizer for generating a frequency-modulated or phase-modulated radiofrequency output signal comprising:

a pre-accentuation filter receiving a frequency modulation digital signal at the input, for pre-accentuating the frequency modulation signal and producing a pre-accentuated frequency modulation signal;

a Σ-Δ modulator having an input receiving the pre-accentuated frequency modulation signal and an output delivering a pre-accentuated and scrambled frequency modulation signal;

a phase locked loop with a variable-ratio frequency divider in the feedback path, the variable-ratio frequency divider having a division ratio control input linked to the output of the Σ-Δ modulator for receiving the pre-accentuated and scrambled frequency modulation signal, the filtering by the phase locked loop making it possible to filter the quantization noise introduced by the Σ-Δ modulator and the pre-accentuation filter applying a pre-accentuation to the frequency modulation signal making it possible to compensate for the effect of this filtering inside a useful band;

means of automatic calibration of the pre-accentuation filter making it possible to adapt the transfer function of the pre-accentuation filter to that of the PLL.

Thus, the low-pass filtering by the PLL makes it possible to eliminate the quantization noise introduced by the Σ-Δ modulator into the PLL, and the pre-accentuation of the modulation signal by the pre-accentuation filter makes it possible to compensate for the effect of this low-pass filtering on the modulation of the output signal Sₒᵤₜ. Finally, the means of automatic calibration of the pre-accentuation filter make it possible to ensure, in the useful band, the tailoring of the transfer function of this filter to that of the PLL in all circumstances.

The pre-accentuation filter, which is a programmable digital filter, is defined by a certain number of coefficients. The invention proposes a digital filter having a transfer function defined judiciously so that just one of these coefficients, called the determining coefficient, depends on the open-loop gain of the PLL. This simplifies a calibration algorithm implemented by the means of automatic calibration of the pre-accentuation filter. Specifically, these means may then comprise a simple table giving, as a function of a parameter of quality of the modulation of the output signal of the synthesizer, the value of the determining coefficient which must be programmed into the pre-accentuation filter. This parameter is preferably the phase error in the output signal when this signal is phase-modulated or the frequency error when this signal is frequency-modulated (mean square error). However, it may also involve the modulation index of the output signal.

Other characteristics and advantages of the invention will become further apparent on reading the description which follows. The latter is purely illustrative and should be read in conjunction with the appended drawings, in which:

FIG. 1, already analyzed is the functional diagram of a DMS known in the state of the art

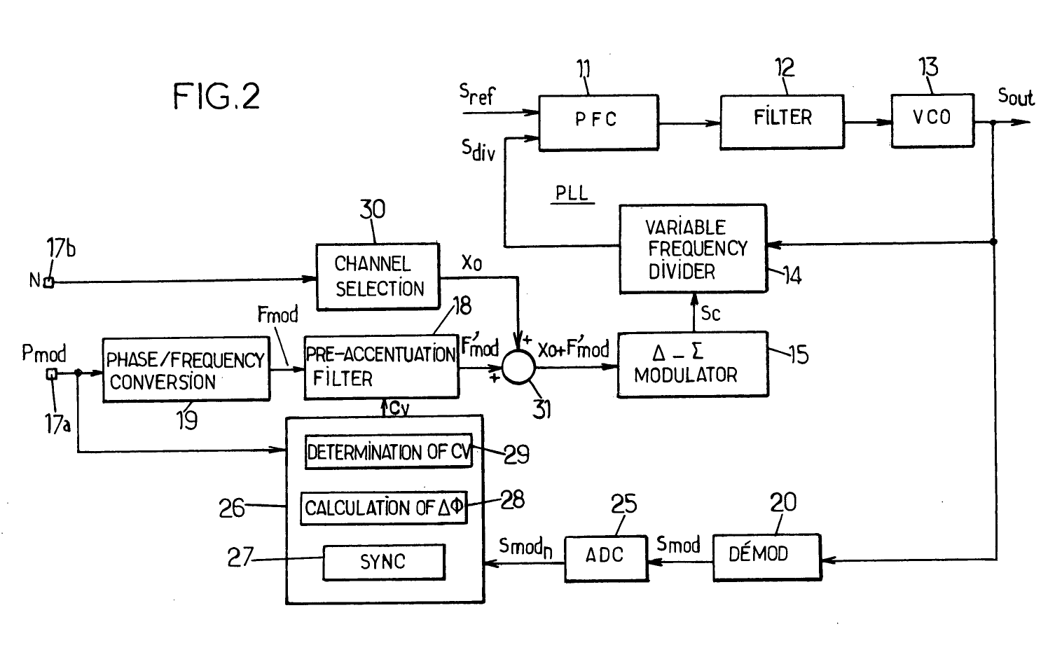

FIG. 2 is the functional diagram of a DMS according to the invention;

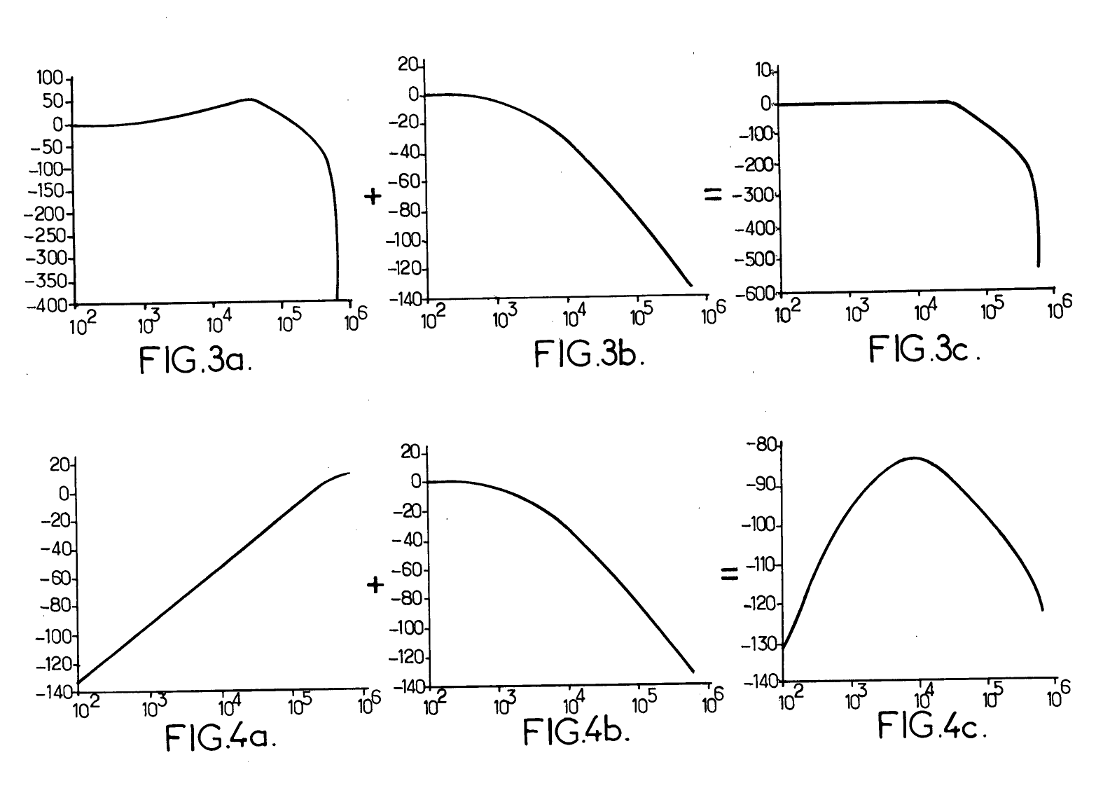

FIGS. 3a to 3c are Bode diagrams showing the transfer function of the DMS according to the invention as regards modulation;

FIGS. 4a to 4c are Bode diagrams showing the transfer function of the DMS according to the invention as regards the quantization noise;

FIG. 5 is a Bode diagram giving a comparison of the transfer functions of the pre-accentuation filter and of the PLL inside a useful band;

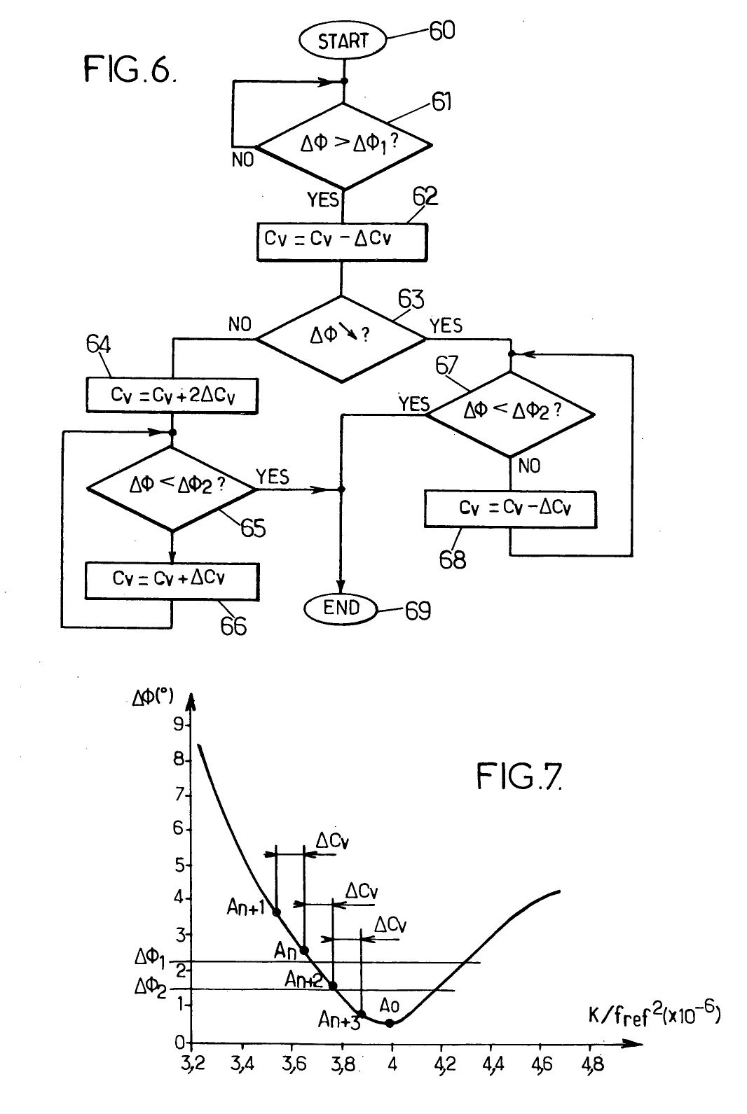

FIG. 6 is a flowchart of the steps of a process for calibrating the pre-accentuation filter;

FIG. 7 is a curve showing the profile of the phase error as a function of the value of the determining coefficient of the pre-accentuation filter;

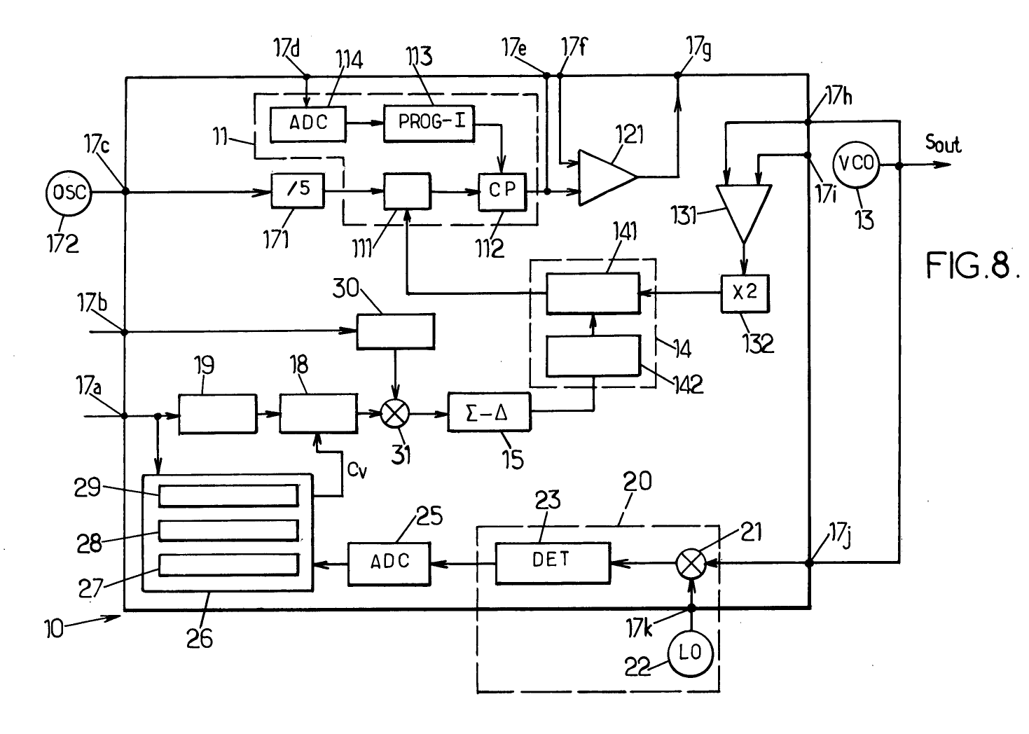

FIG. 8 is a functional diagram of an integrated circuit integrating the digital means of the DMS according to the invention.

In FIG. 2, in which the same elements as in FIG. 1 bear the same references, a functional diagram of a DMS according to the invention has been represented.

The DMS according to the invention comprises a PLL and a Σ-Δ modulator of the same structure as the respective ones of the DMS of FIG. 1. According to a characteristic of the invention, the loop filter 12 of the PLL of the DMS of FIG. 2 is an integrator having an integration stage, whose cutoff frequency is adjusted in such a way that the low-pass filtering introduced by the PLL makes it possible to filter the quantization noise introduced by the Σ-Δ modulator into the spectrum of the output signal Sₒᵤₜ. In one example, the cutoff frequency f_{c} of the transfer function of the PLL is of the order of 5 kHz for a sampling frequency of the Σ-Δ modulator equal to 12.8 MHz.

In the present description of an embodiment of the invention, the example of a DMS making it possible to generate a phase-modulated signal is considered. In this embodiment, the DMS comprises a data input 17a for receiving a phase modulation digital signal P_{mod} and a conversion circuit 19 receiving the signal P_{mod} at input. This circuit 19 has the function of producing the frequency modulation signal F_{mod} at output, by carrying out a phase/frequency conversion of the signal P_{mod}. This is not however limiting and a DMS according to the invention can also be used to generate a frequency-modulated signal. The value of the maximum frequency f_{mod} of the useful band of the phase modulation signal P_{mod} and of the frequency modulation signal F_{mod} lies in the 8-16 kHz band. It is therefore typically greater than the value of the cutoff frequency f_{c} of the transfer function of the PLL which is, as indicated previously, substantially equal to 5 kHz in the example. The low-pass filtering by the PLL therefore has an effect on the modulation of the output signal Sₒᵤₜ.

This is why, in order not to impair the modulation of the output signal Sₒᵤₜ, the DMS according to the invention is moreover distinguished from that of FIG. 1 in that it comprises a pre-accentuation filter 18 which receives the frequency modulation signal F_{mod} at input. This filter 18 has the function of pre-accentuating the signal F_{mod} so as to produce at output a pre-accentuated frequency modulation signal F′_{mod}. More particularly, it will be seen later that the filter 18 has the function of applying a pre-accentuation to the frequency modulation signal F_{mod}, making it possible, in a useful band, to compensate for the low-pass filtering by the PLL.

In an example, the DMS furthermore comprises an input 17b for receiving a channel number NC, and a channel selection module 30 receiving the channel number NC at input. This module 30 has the function of generating, from the channel number NC, a channel signal X₀ which is a digital signal defining a determined radiofrequency channel from a plurality of channels covered by the transmitter incorporating the DMS. The module 30, which is for example embodied in software form, can operate by selecting the digital signal X₀ from a table indexed by the channel number NC. The DMS then comprises a digital adder 31 for adding together the channel signal X₀ and the pre-accentuated frequency modulation signal F′_{mod}, and for delivering the resulting signal X₀+F′_{mod} on the first input of the modualtor 15.

Stated otherwise, the digital adder 31 comprises a first input connected to the output of the channel selection module 30 for receiving the channel signal X₀, a second input connected to the output of the pre-accentuation filter 18 for receiving the pre-accentuated frequency modulation signal F′_{mod}, and an output connected to the first input of the modulator 15 for delivering thereto the signal X₀+F′_{mod}. At the output of the digital adder 31, the high-order bits of the resulting signal X₀+F′_{mod} consist for example of the bits of the channel signal X₀, while its low-order bits consist of the bits of the pre-accentuated frequency modulation signal F′_{mod}. The channel selection module 30 and the digital adder 31 allow the transmitter incorporating the DMS to cover a plurality of different channels. They are not however compulsory and the output of the pre-accentuation filter 18 can be connected directly to the first input of the modulator 15 so as to deliver thereto the pre-accentuated frequency modulation signal F′_{mod}, when the DMS is incorporated into a single-channel transmitter. It will be noted that, applied alone (without the pre-accentuated frequency modulation signal F′_{mod}), the channel signal X₀ engenders the synthesis of an output signal Sₒᵤₜ with a constant frequency fₒᵤₜ.

The pre-accentuation filter 18 is a programmable digital filter with transfer function A(z) which is determined by the value of coefficients Cⱼ stored in a memory. It is recalled that, according to the invention, the filter 18 makes it possible to compensate for the low-pass filtering by the PLL in a useful band comprising the cutoff frequency f_{mod} of the frequency modulation signal F_{mod}. Specifically, so as not to delete the frequency modulation in the signal Sₒᵤₜ at the output of the PLL, the pre-accentuation filter 18 applies a pre-accentuation to the frequency modulation signal F_{mod}, which makes it possible to compensate for the effect on the modulation of the low-pass filtering by the PLL. In order for this compensation to be effective, the transfer function A(z) is matched to the actual transfer function of the PLL.

Specifically, as shown in the Bode diagram of FIG. 5, the transfer function, represented by the curve 32, of the pre-accentuation filter 18 is symmetric with that of the PLL, represented by a curve 31, with respect to a horizontal line corresponding to the constant response of the PLL in the low frequencies. In the figure, this constant response corresponds to a gain equal to unity (0 dB), so that said horizontal line passes through the origin of the ordinate axis on which the gain values are expressed in decibels (dB). It will be noted that the aforesaid symmetry between the transfer function of the pre-accentuation filter 18 and that of the PLL does not need to be obtained throughout the entire spectrum. It is in fact sufficient to obtain it inside a useful band which includes the maximum frequency f_{mod} of the frequency modulation signal F_{mod}. In the example, since this frequency f_{mod} lies between 8 and 16 kHz, the symmetry between the transfer functions 31 and 32 of the PLL and the pre-accentuation filter 18 respectively is obtained for example up to at least 30 kHz. As shown by the dashed curve 33, the overall response of the synthesizer as regards modulation is then constant inside the 0-30 kHz band.

Represented respectively in the Bode diagrams of FIGS. 3a and 3b are the transfer functions of the pre-accentuation filter 18 and of the PLL as regards modulation. The horizontal axis is graduated in hertzs and the vertical axis in decibels. The combination of these transfer functions represents the overall filtering applied to the frequency modulation signal F_{mod} by the DMS according to the invention, whose transfer function as regards modulation is represented in the Bode diagram of FIG. 3c. As may be seen in this latter figure, the frequency modulation signal F_{mod} is not attenuated in a useful band stretching at least as far as 30 kHz, in spite of the low-pass filtering introduced by the PLL in this band, this being by virtue of the corresponding pre-accentuation introduced by the pre-accentuation filter 18.

Conversely, represented in the Bode diagrams of FIGS. 4a and 4b are respectively the transfer functions of the modulator and of the PLL as regards the quantization noise introduced by the modulator 15. The combination of these transfer functions represents the overall filtering applied to this quantization noise by the DMS according to the invention, whose transfer function is represented in the Bode diagram of FIG. 4c. As may be seen in this latter figure, the quantization noise introduced by the modulator 15 is strongly attenuated in the useful band (attenuation of greater than 80 dB), this corresponding to satisfactory rejection of the quantization noise.

As indicated previously, it is important that the transfer function of the pre-accentuation filter be matched to the actual transfer function of the PLL. Now, the cutoff frequency f_{c} of the transfer function of the PLL depends on the open-loop gain K of the PLL. This gain is given by the expression:

$$K = \frac{{I}_{cp} \times {K}_{vco}}{C \times \overline{N}} \qquad ( 2 )$$

where I_{cp} denotes the current in the charge pump of the PFD.

where K_{vco} is the slope of the VCO;

where C is the capacitance of the integrator 12, determined by the value of a capacitor (external analog component);

and where \overline{N} is the mean division ratio of the frequency divider 14.

A drawback stems from the fact that the value K_{vco} depends on the operating temperature of the synthesizer, and also on the synthesized frequency fₒᵤₜ. Moreover, the values of K_{vco}, C and I_{cp} exhibit a spread in their characteristics which also has an impact on the value of the cutoff frequency f_{c} of the PLL. Thus, for a given VCO, K_{vco} may experience a spread of plus or minus 25% as a function of fₒᵤₜ and the variations due to temperature and to spread in the characteristic may be responsible for a variation in K_{vco} of the order of 28%. To a lesser extent, the value C also depends on the operating temperature of the synthesizer and on the synthesized frequency fₒᵤₜ. Furthermore, the value of C can vary from 1 to 10% according to the specimens of the external capacitor. Finally, the value of I_{cp}, which depends essentially on the accuracy of the digital check implemented by means of a 6-bit analog/digital converter, may vary by 2%. Furthermore, the aging of the analog components also induces a variation, in the longer term, of the values of K_{vco}, C and I_{cp}. As a result of all these variations, the cutoff frequency f_{c} of the actual transfer function of the PLL depends on the analog components used for the manufacture of the specimen of the DMS, and it may vary during the operation of the DMS with the rise in temperature, and in the longer term with the aging of the analog components.

All these variations may be compensated for, according to the invention, by virtue of the means of automatic calibration of the pre-accentuation filter 18. The calibration of the filter 18 effected by these means is said to be automatic in the sense that it does not require manual adjustment by an operator. This makes it possible to permit the industrial manufacture of a DMS according to the invention under realistic economic conditions. The expression “calibration of the pre-accentuation filter” is understood to mean a dynamic adapting of the transfer function of the filter so as to match it to the actual transfer function of the PLL, in such a way that the pre-accentuation filter correctly fulfills, in all circumstances, its function of compensating for the effect on the modulation of the low-pass filtering by the PLL. In order to take account of the effect of the spread in the characteristics of the components on K_{vco} C and/or I_{cp}, and also of the effect of the aging of the analog components which are involved, these calibration means are activated when the transmitter is switched on. Moreover, in order to take account of the rise in operating temperature during the operation of the transmitter, they are also activated at regular time intervals in the course of this operation.

In order to describe the structure and the operation of the means of calibration of the pre-accentuation filter 18, a judicious transfer function which is accorded to this filter in a preferred embodiment is firstly described in what follows.

For a PLL whose loop filter 12 is an integrator and whose PFC comprises a charge pump, it is possible according to the invention to choose a pre-accentuation filter 18 whose transfer function A(z), expressed as a function of the variable z, may be written in the following form:

$$A ( z ) = {[ BL ( \frac{1}{1 + \frac{{s}^{2}}{K} \times \frac{1}{F ( s )}} ) ]}^{- 1} \qquad ( 3 )$$

where s denotes the Laplace variable;

where BL denotes the bilinear transform, which makes it possible to go from an expression as a function of the variable s to an expression as a function of the variable z;

where K denotes the open-loop gain of the PLL;

and where F(s) is the Laplace transform of the integrator filter 12 of the PLL disregarding the integration stage of this filter.

For a third-order loop filter, the Laplace transform F(s) can be expressed by:

$$F ( s ) = \frac{1 + \frac{s}{{R}_{4} {C}_{4}}}{( 1 + \frac{s}{{R}_{1} C1} ) \times ( 1 + \frac{s}{{R}_{2} {C}_{2}} ) \times ( 1 + \frac{s}{{R}_{3} {C}_{3}} )} \qquad ( 4 )$$

where the Rᵢ and the Cᵢ respectively denote values of resistance and of capacitance.

Thanks to the linearity property of the bilinear function BL, the expression (3) can be cast into the form:

$$A ( z ) = [ 1 + \frac{1}{K} \times {f}_{ref}^{2} \times {( 1 - {z}^{- 1} )}^{2} \frac{1}{BL ( F ( s ) )} ] \qquad ( 5 )$$

In the above expression (5), the open-loop gain K of the PLL appears only in a single coefficient of the transfer function of the pre-accentuation filter 18, subsequently called the determining coefficient. This determining coefficient is denoted Cᵥ. It is given by:

$${C}_{v} = \frac{{f}_{ref}^{2}}{K} \qquad ( 6 )$$

To summarize, the values I_{cp} K_{vco} and C, which come into the expression (2) for the open-loop gain K of the PLL, appear only in the determining coefficient Cᵥ of the transfer function of the pre-accentuation filter 18. Stated otherwise, with a pre-accentuation filter exhibiting a judiciously chosen transfer function such as this, only the determining coefficient Cᵥ has to be modified to take account of the variations of I_{cp}, K_{vco} and C. This allows simple adaptation of the transfer function of the pre-accentuation filter 18 to the actual transfer function of the PLL.

Returning to the diagram of FIG. 2, the structure of the means of automatic calibration of the pre-accentuation filter 18 will now be described.

These means comprise an auxiliary loop comprising means 20 for demodulating the output signal Sₒᵤₜ an analog/digital converter 25 and a calculation unit 26. The demodulation means 20 produce, from the output signal Sₒᵤₜ, an analog signal S_{mod} which corresponds to the modulation of the output signal Sₒᵤₜ For example, if the signal Sₒᵤₜ is a phase-modulated signal of the form Sₒᵤₜ(t)=M.cos(2.Π.f_{ref}.t+m.φₘ(t)), where M and m are real numbers and where φₘ(t) represents the phase modulation, then the signal S_{mod} is of the form S_{mod}(t)=m.φₘ(t). The calculation unit 26 being a digital processing unit, the analog signal S_{mod} is converted into a digital signal S_{mod}_{ₙ} by means of the converter 25. The digital signal S_{mod}_{ₙ} is then transmitted as input to the calculation unit 26.

It is recalled that in the present exemplary embodiment, the output signal Sₒᵤₜ is a phase-modulated radiofrequency signal. A parameter of quality of the modulation of the output signal Sₒᵤₜ taken into account is therefore preferably the phase error of the output signal Sₒᵤₜ, and the calculation unit 26 comprises a synchronization module 27. This module 27 has the function of synchronizing the signal S_{mod}_{ₙ} and the phase modulation signal P_{mod}, in such a way as to take account of the delay of the signal S_{mod}_{ₙ} and with respect to the signal P_{mod} which results from the processing by the DMS. The module 27 applies an ad-hoc delay to the phase modulation signal P_{mod}, making it possible to compensate for the aforesaid delay. This ad-hoc delay is calculated by maximization of the autocorrelation of the phase error by the synchronization module 27. Equivalent means are provided when, the output signal Sₒᵤₜ being a frequency-modulated radiofrequency signal, a parameter of quality of the modulation of the output signal Sₒᵤₜ taken into account is the frequency error of the output signal Sₒᵤₜ. However, they are not useful when, the output signal Sₒᵤₜ being a frequency-modulated or phase-modulated radiofrequency signal, the parameter of quality of the modulation of the output signal Sₒᵤₜ is the modulation index of the output signal Sₒᵤₜ.

The calculation unit 26 furthermore comprises a module 28 for calculating a parameter of quality of the modulation of the output signal Sₒᵤₜ, namely in the example the phase error Δφ between the phase modulation signal P_{mod} and the signal S_{mod}_{ₙ} corresponding to the output signal Sₒᵤₜ. This is for example the mean square error or R.M.S. error (the abbreviation standing for “Root Mean Square”).

The calculation unit 26 finally comprises a module for determination of the value of the determining coefficient Cᵥ. This module operates by selecting from a table containing Z predetermined values of the coefficient Cᵥ. Such a table is for example stored in a read-only non-volatile memory such as the ROM memory of a microcontroller. The values of the coefficient Cᵥ which are available in this table are for example values which increase regularly, with a constant increment Cᵥ. The selection is made as a function of the phase error Δφ produced by the calculation module 28 according to an algorithm to which we shall return later. In the case of a DMS incorporated into a multi-channel transmitter envisaged here, it will be noted that it may be preferable to employ such a table for each channel or group of channels covered by the transmitter, since the values of the coefficient Cᵥ may depend on the frequency of the channel selected by the channel selection circuit 30.

The modules 27, 28 and 29 are for example software modules embodied in the form of programs stored in the ROM memory of a microcontroller and executed by said microcontroller when the calibration means are activated.

When the DMS is made operational, the pre-accentuation filter 18 is programmed successively with the Z values of the determining coefficient Cᵥ which are stored in the table of values which is associated with the selected channel, and the phase error Δφ of the output signal Sₒᵤₜ is calculated for each of it. That one of the values of the coefficient Cᵥ which is the best, that is the one which gives the smallest value of Δφ, is then chosen and is programmed into the pre-accentuation filter 18. Stated otherwise, the Z available values of the determining coefficient Cᵥ are tested and the best of these values is selected and is then programmed into the pre-accentuation filter 18. Preferably, these successive tests are carried out successively for identical values of the frequency modulation signal S_{mod}, that is also of the phase modulation signal P_{mod}. This guarantees that the calculation of the phase error is not influenced by the value of this signal. In an example, the tests of the Z values of Cᵥ are carried out during the transmission of the learning sequence which, customarily, is transmitted when the transmitter incorporating the DMS is powered up. It is in fact known that this learning sequence is a string of identical binary words.

While operational, the calculation unit 26 of the means of automatic calibration of the pre-accentuation filter 18 implements an algorithm which will now be described in conjunction with the flowchart of FIG. 6 and the curve of FIG. 7.

Represented in FIG. 7 is a curve showing, for a determined selected channel and for determined values of K_{vco}, C and I_{cp}, the profile of the phase error Δφ as a function of the value of the determining coefficient Cᵥ of the pre-accentuation filter 18. A₀ denotes the point of this curve which would correspond to the selected value of the coefficient Cᵥ when the DMS is made operational. As may be seen, the point A₀ corresponds to a minimum of the curve. Aₙ denotes the point of the curve which corresponds to the current value of the coefficient Cᵥ programmed into the filter 18 at a determined instant at which the means of automatic calibration of the filter 18 are activated.

Preferably, the means of automatic calibration of the pre-accentuation filter are activated during the transmission by a transmitter incorporating the DMS of the synchronization sequences which, conventionally, are transmitted at regular time intervals, for example every 20 ms in data transmission mode. Since these synchronization sequences consist of strings of identical binary words, the automatic calibration of the filter 18 is not influenced by the value of the modulation signal. Specifically, the value of the phase error Δφ is thus calculated during the transmission of these synchronization sequences, that is for identical values of the frequency modulation signal.

The algorithm for automatic calibration of the pre-accentuation filter 18 represented by the flowchart of FIG. 6 is implemented by the module 29 of the calculation unit 26 of the DMS according to the invention. It is assumed by hypothesis, that at the start 60 of the algorithm, a determined value of the coefficient Cᵥ is stored in the filter 18, so that situation is at the point Aₙ on the curve of FIG. 7.

In a step 61, the phase error Δφ produced by the calculation module 28 of the calculation unit 26 of the DMS is compared with a first threshold value Δφ₁. If Δφ is not greater than Δφ₁, then it is jumped back to the start 60. If conversely Δφ is greater than Δφ₁, then in a step 62 the value of the determining coefficient Cᵥ is replaced with its current value minus the increment ΔCᵥ. In an example, this new current value of the determining coefficient Cᵥ causes the operating point of the DMS to move along the curve of FIG. 7 from the point Aₙ to the point Aₙ₊₁.

A step 63 then determines as a function of a new value of the phase error Δφ produced by the calculation module 28 whether the phase error has decreased with respect to the previous value of the coefficient Cᵥ. If the phase error has not decreased, then this signifies that the value of the coefficient Cᵥ has not been modified in the right direction. This is why in a step 64 the current value of the coefficient Cᵥ is then replaced with the current value increased by twice the increment ΔCᵥ. Because of this modification of the current value of the coefficient Cᵥ, the operating point of the DMS moves along the curve of FIG. 7 from the point Aₙ₊₁ to the point Aₙ₊₂. In a step 65 the phase error Δφ calculated by the calculation module 28 of the calculation unit 26 is then compared with a second threshold value Δφ₂. If Δφ is less than Δφ₂, the end 69 of the algorithm is reached. If Δφ is not less than Δφ₂, then the value of the determining coefficient Cᵥ must be modified again in the same direction. This is why in a step 66 the current value of the coefficient Cᵥ is replaced with the current value increased by the increment ΔCᵥ, and it is jumped back to the aforesaid comparison step 65. In the example, represented in FIG. 7, this new current value of the coefficient Cᵥ causes the operating point of the DMS to move along the curve from the point Aₙ₊₁ to the point Aₙ₊₂. In the example represented, the point Aₙ₊₂ is still above the threshold Δφ₂, so that a new iteration of steps 66 and 65 is required before reaching the end 69 of the algorithm. The operating point of the DMS then corresponds to the point Aₙ₊₃ of the curve of FIG. 7.

If in step 63 it is determined conversely that the value of the phase error Δφ has decreased, then in a step 67, comparable to the aforesaid step 65, the value of the phase error Δφ is compared with the second threshold value Δφ₂. If Δφ is less than Δφ₂, then the end 69 of the algorithm is reached. Conversely, if Δφ is not less than Δφ₂, then in a step 68 the current value of the coefficient Cᵥ is replaced with the current value decreased by the increment ΔCᵥ and it is jumped back to the aforesaid comparison step 67.

The threshold value Δφ₂ is less than the threshold value ΔC₁. In an example, Δ0₁ is of the order of 2° and Δφ₂ is of the order of 1.5°. The algorithm described above in conjunction with FIG. 6 therefore makes it possible to keep the phase error Δφ of the output signal Fₒᵤₜ at most to a value of the order of 2°. Having two different threshold values Δφ₁ and Δφ₂, with Δφ₂ being less than Δφ₁, enables the algorithm implemented by the determination module 29 of the calculation unit 26 of the DMS to introduce a hysteresis into the profile of the operating point.

Represented in FIG. 8 is the functional diagram of an integrated circuit 10 in which are integrated all the digital means implemented in the DMS according to the invention. In this figure, the same elements as in FIG. 2 bear the same references.

In addition to the inputs 17a and 17b already described with reference to FIG. 2, the circuit 10 comprises an input 17c and a frequency divider 171. During operation, the input 17c is connected to an external oscillator 172 such as a quartz, and delivers a clock signal whose frequency is a few MHz, on an input of the divider 171. The latter performs a division of the frequency of the clock signal by five, and outputs the reference signal S_{ref}. The phase/frequency comparator 11 here comprises a comparator 111, a first input of which is connected to the output of the divider 171 for receiving the signal S_{ref} and a second input of which is connected to the output of the variable-ratio frequency divider 14. It further comprises a charge pump 112. The charge pump 112 receives a digital signal for controlling current delivered by the output of a programming circuit 113. The circuit 113 receives as input a digital signal delivered by an analog/digital converter 114. The latter is connected to an input 17d of the circuit 10 for receiving an analog signal for controlling the current of the charge pump 112. This control signal, after analog/digital conversion by means of the converter 114, is used by the programming circuit 113 to deliver the digital signal for controlling the current to the charge pump. The output of the charge pump 112 coincides with the output of the PFC 11.

From the filter 12, the circuit 10 comprises only an operational amplifier 121, a first input of which is connected to the output of the PFC 11 as well as to an input 17e of the circuit 10, a second input of the operational amplifier 121 being connected to another input 17f of the circuit 10. During operation, these two inputs 17e and 17f are linked to external discrete components, including two capacitors and a resistor which, together with the operational amplifier 121, form an integrator whose cutoff frequency is determined by the value of said capacitors and of said resistor. The output of the operational amplifier 121 is linked to an output 17g of the circuit 10.

It will be noted that the VCO is not integrated into the circuit 10 but is an external circuit. For the sake of simplification, the input of the VCO 13, which during operation, is connected to the output 17g of the filter 12 is not represented in FIG. 8. The circuit 10 comprises an input 17h which, during operation, is connected to the output of the VCO 13 so as to receive the output signal Sₒᵤₜ. It further comprises an input 17i which, during operation, is linked to the ground potencial. It comprises an operational amplifier 131 operating as an analog comparator, the inputs of which are connected respectively to the input 17h and to the input 17i of the circuit 10, and the output of which is connected to the input of the variable-ratio frequency divider 14 via a frequency doubler 132.

In the diagram of FIG. 8, the variable-ratio frequency divider 14 comprises a frequency divider 141 coupled to a combinatorial logic block 142. The input of the combinatorial logic block is connected to the output of the Σ-Δ modulator 15 and constitutes the control input for the division ratio of the variable-ratio frequency divider 14.

From the demodulation means 20, the circuit 10 comprises a frequency mixer 21 and a frequency detector 23. The mixer 21 comprises a first input which is connected to an input 17j of the circuit 10 and a second input which is connected to an input 17k of the circuit 10. During operation, these inputs 17j and 17k are connected respectively to the output of the VCO 13 so as to receive the output signal Sₒᵤₜ and to the output of a local oscillator 22, which is also external with respect to the circuit 10 so as to receive a signal at an intermediate frequency. The output of the mixer 21, is connected to an input of the detector 23, the output of which corresponds to the output of the demodulation means 20, and is therefore connected to the input of the analog/digital converter 25.

As may be observed in the diagram of FIG. 8, the circuit 10 integrates most of the means of the DMS. only the analog means consisting of the VCO 13, the local oscillator 22, the oscillator 172, and the resistor and the capacitor of the integrator 12 are external components with respect to the circuit 10. The invention therefore allows the embodiment of a DMS with a high degree of integration. The embodiment of a DMS according to the invention is therefore inexpensive and can be envisaged in mass-production applications. All this is especially advantageous in the case of mobile telephony equipment.

1. A digital modulation synthesizer for generating a frequency-modulated or phase-modulated radiofrequency output signal (Sₒᵤₜ) comprising:
a pre-accentuation filter (18) receiving a frequency modulation digital signal (F_{mod}) at the input, for pre-accentuating the frequency modulation signal (F_{mod}) and producing a pre-accentuated frequency modulation signal (F′_{mod});
a Σ-Δ modulator (15) having an input receiving the pre-accentuated frequency modulation signal (F′_{mod}) and an output delivering a pre-accentuated and scrambled frequency modulation signal (S_{c});
a phase locked loop (PLL) with a variable-ratio frequency divider (14) in the feedback path, the variable-ratio frequency divider (14) having a division ratio control input linked to the output of the Z-A modulator (15) for receiving the pre-accentuated and scrambled frequency modulation signal (S_{c}), the filtering by the phase locked loop (PLL) making it possible to filter the quantization noise introduced by the Σ-Δ modulator (15) and the pre-accentuation filter (18) applying a pre-accentuation to the frequency modulation signal (F_{mod}) making it possible to compensate for the effect of this filtering inside a useful band;
means of automatic calibration of the pre-accentuation filter (18) making it possible to adapt the transfer function of the pre-accentuation filter (18) to that of the PLL.

2. The synthesizer as claimed in claim 1, furthermore comprising a data input (17a) for receiving a phase modulation signal (P_{mod}), and a phase/frequency conversion circuit (19) receiving the phase modulation signal (P_{mod}) at input so as to produce the frequency modulation signal (F_{mod}) at output.

3. The synthesizer as claimed in claim 1 or claim 2, furthermore comprising an input (17b) for receiving a channel number (NC), a channel selection module (30) receiving the channel number (NC) at input so as to produce at output a channel digital signal (X₀), and a digital adder (31) having a first input for receiving the channel signal (X₀), a second input for receiving the pre-accentuated frequency modulation signal (F′_{mod}), and an output linked to the input of the Σ-Δmodulator (15) for delivering thereto a signal whose high-order bits are the bits of the channel signal (X₀) and whose low-order bits are the bits of the pre-accentuated frequency modulation signal (F′_{mod}).

4. The synthesizer as claimed in any one of the preceding claims, in which the pre-accentuation filter (18) is a programmable digital filter whose transfer function is determined by coefficients recorded in a memory, and just one of which, called the determining coefficient, is dependent on the open-loop gain (K) of the PLL.

5. The synthesizer as claimed in claim 4 in which, the PLL comprising a phase/frequency comparator (11) with a charge pump and an integrator (12) having an integration stage, the transfer function A(z) of the pre-accentuation filter (18), expressed as a function of the variable z, is of the type:
$$A ( z ) = [ 1 + \frac{1}{K} \times {f}_{ref}^{2} \times {( 1 - {z}^{- 1} )}^{2} \frac{1}{BL ( F ( s ) )} ]$$
where K is the open-loop gain of the PLL;
where f_{ref} denotes a reference frequency of the PLL;
where BL denotes the bilinear transform;
and where F(s) is the Laplace transform of the integrator filter (12) of the PLL disregarding the integration stage.

6. The synthesizer as claimed in one of the preceding claims, in which the means of automatic calibration of the pre-accentuation filter (18) comprise an auxiliary loop comprising means of demodulation (20) of the output signal (Sₒᵤₜ) and a calculation unit (26), the calculation unit (26) comprising a module (28) for calculating a parameter of quality of the modulation of the output signal (Sₒᵤₜ) and a module (29) for determination of the determining coefficient of the pre-accentuation filter (18) as a function of said parameter.

7. The synthesizer as claimed in claim 6, in which, the modulation being a phase modulation, the parameter of quality of the modulation of the output signal (Sₒᵤₜ) is the phase error (Δφ) of the output signal (Sₒᵤₜ).

8. The synthesizer as claimed in claim 6, in which, the modulation being a frequency modulation, the parameter of quality of the modulation of the output signal (Sₒᵤₜ) is the frequency error of the output signal (Sₒᵤₜ).

9. The synthesizer as claimed in claim 6, in which, the modulation being a phase modulation or frequency modulation, the parameter of quality of the modulation of the output signal (Sₒᵤₜ) is the modulation index of the output signal (Sₒᵤₜ).

10. The synthesizer as claimed in any one of claims 4 to 9, comprising means for, when making operational, successively testing determined values of the determining coefficient, selecting the best of these values and programming it into the pre-accentuation filter (18).

11. The synthesizer as claimed in claim 10, comprising means for successively testing said values of the determining coefficient for identical values of the frequency modulation signal (S_{mod}).

12. The synthesizer as claimed in claim 11, comprising means for successively testing said values of the determining coefficient during the transmission of a learning sequence by a radiofrequency transmitter incorporating the synthesizer.

13. The synthesizer as claimed in any one of claims 6 to 12, comprising means for, while operational, comparing the parameter of quality of the modulation of the output signal (Sₒᵤₜ) with a first threshold (φ1) and with a second threshold (φ2) less than said first threshold (φ1), and means for, as soon as the parameter of quality of the modulation of the output signal (Sₒᵤₜ) is greater than said first threshold (φ1), modifying the value of the determining coefficient programmed into the pre-accentuation filter (18) until the parameter of quality of the modulation of the output signal (Sₒᵤₜ) is less than said second threshold (φ2).

14. The synthesizer as claimed in claim 13, comprising means for calculating the value of the parameter (Δφ) of quality of the modulation of the output signal (Sₒᵤₜ) for identical values of the frequency modulation signal (F_{mod}).

15. The synthesizer as claimed in claim 14, comprising means for calculating the value of the parameter (Δφ) of quality of the modulation of the output signal (Sₒᵤₜ) during the transmission of a synchronization sequence by a radiofrequency transmitter incorporating the synthesizer.

16. The synthesizer as claimed in one of claims 6 to 15, comprising a memory for storing determined values of the determining coefficient.

17. The synthesizer as claimed in one of the preceding claims, in which all the digital means are integrated into an integrated circuit.
